(19) United States
(12) Patent Application Publication
(10) Pub. No.: US 2026/0173714 A1
(43) Pub. Date: Jun. 18, 2026

(54) DISPLAY DEVICE AND ELECTRONIC DEVICE INCLUDING THE SAME

(71) Applicant: Samsung Display Co., LTD., Yongin-si (KR)

(72) Inventors: EUNWON SEO, Yongin-si (KR); JOON-IK LEE, Yongin-si (KR); SIWOONG LEE, Yongin-si (KR); JUNHEE SON, Yongin-si (KR); HAENGWON PARK, Yongin-si (KR); BYOUNG DAE YE, Yongin-si (KR)

(21) Appl. No.: 19/286,860

(22) Filed: Jul. 31, 2025

(30) Foreign Application Priority Data
Dec. 17, 2024 (KR) 10-2024-0188901

(51) Int. Cl. H10K 59/80; H10K 77/10; H10K 102/00

(52) U.S. Cl. CPC H10K 59/871; H10K 77/111; H10K 2102/311

(57) ABSTRACT

A display device includes a display panel including a first area including a display area, a second area, and a bending area disposed between the first area and the second area in an unfolded state, a metal plate disposed under the display panel in the first area, directly contacting the display panel, and at least partially protruding from the first area to the bending area in a plan view, a protective film disposed under the display panel in the second area and protruding from the second area to the bending area further than the metal plate protrudes from the first area to the bending area when the display panel is in a bent state in the plan view, and a filler material disposed under the display panel in the bending area and filling a space between the metal plate and the protective film

This application claims priority to Korean Patent Application No. 10-2024-0188901, filed on Dec. 17, 2024, and all the benefits accruing therefrom under 35 U.S.C. § 119, the content of which in its entirety is herein incorporated by reference.

### BACKGROUND

### 1. FIELD

The disclosure relates to a display device and an electronic device including the same. More specifically, the disclosure relates to the display device that provides visual information and the electronic device including the same.

### 2. DESCRIPTION OF THE RELATED ART

Recently, flat panel display devices have been studied and developed in various ways. The flat panel display devices are being used in a wider range of applications because they are thin and light. In addition, the flat panel display devices have recently become flexible, making them easier to carry and increasing their application targets.

The flat panel display devices with flexibility are advantageous in reducing a size of the display device or improving visibility at various angles because they may be bent or folded. However, because the display device is thin, defects may easily occur during manufacturing process, manufacturing costs are high, and the lifespan of the display device may be reduced due to stress caused by bending. Accordingly, attempts are being made to improve a durability of the display device that is bent, thereby increasing a lifespan of the display device.

### SUMMARY

One purpose of the disclosure is to provide a display device with improved reliability.

Another purpose of the disclosure is to provide an electronic device including the display device.

A display device in an embodiment of the disclosure includes a display panel including a first area including a display area, a second area, and a bending area disposed between the first area and the second area in an unfolded state, a metal plate disposed under the display panel in the first area, directly contacting the display panel, and at least partially protruding from the first area to the bending area in a plan view, a protective film disposed under the display panel in the second area and protruding from the second area to the bending area further than the metal plate protrudes from the first area to the bending area when the display panel is in a bent state in the plan view, and a filler material disposed under the display panel in the bending area and filling a space between the metal plate and the protective film.

In an embodiment, a curvature radius of the bending area of the display panel may be about 0.5 millimeter (mm) or less.

In an embodiment, the display device may further include a cover panel disposed between the metal plate and the protective film when the display panel is in the bent state and protecting the display panel.

In an embodiment, the filler material may contact at least a portion of one side of the cover panel.

In an embodiment, the filler material may include at least one selected from a group including a silicon-based resin, an acrylic-based resin, and a urethane-based resin.

In an embodiment, the display device may further include a bending protection layer disposed on the display panel in the bending area.

In an embodiment, the filler material and the bending protection layer may include a same material as each other.

In an embodiment, the display panel may include a substrate including polyimide.

A display device in another embodiment of the disclosure includes a display panel including a first area including a display area, a second area, and a bending area disposed between the first area and the second area in an unfolded state, a metal plate disposed under the display panel in the first area, directly contacting the display panel, and including an engraved pattern defined in a thickness direction of the metal plate at a portion next (adjacent) to the bending area protective film disposed under the display panel in the second area, and a filler material disposed under the display panel in the bending area and filling a space between the metal plate and the protective film.

In an embodiment, the engraved pattern may include multiple holes defined in the metal plate and penetrating in the thickness direction of the metal plate.

In an embodiment, the engraved pattern may include grooves partially removed from the thickness direction of the metal plate in the plan view.

In an embodiment, the filler material may cover at least a portion of an upper surface of the engraved pattern.

In an embodiment, a curvature radius of the bending area of the display panel may be about 0.5 mm or less.

In an embodiment, the display device may further include a cover panel disposed between the metal plate and the protective film when the display panel is in the bent state and protecting the display panel.

In an embodiment, the filler material may include at least one selected from a group including a silicon-based resin, an acrylic-based resin, and a urethane-based resin.

In an embodiment, the display device may further include a bending protection layer disposed on the display panel in the bending area.

In an embodiment, the filler material and the bending protection layer may include a same material as each other.

In an embodiment, the display panel may include a substrate including polyimide.

An electronic device in an embodiment of the disclosure includes a housing and a display device accommodated by the housing and configured to display images, and the display device including a display panel including a first area including a display area, a second area, and a bending area disposed between the first area and the second area, a metal plate disposed under the first area, directly contacting the display panel, and at least partially protruding from the first area to the bending area in a plan view, a protective film disposed under the second area and protruding from the second area to the bending area further than the metal plate protrudes from the first area to the bending area when the display panel is in a bent state in the plan view, and a filler material disposed under the bending area and filling a space between the metal plate and the protective film.

A display device in an embodiment of the disclosure may include a display panel including a first area including a display area, a second area, and a bending area disposed between the first area and the second area, a metal plate disposed under the first area, directly contacting the display panel, and at least partially protruding from the first area to the bending area in the plan view, a protective film disposed under the second area and protruding from the second area to the bending area further than the metal plate protrudes from the first area to the bending area in the plan view, and a filler material disposed under the bending area and filling a space between the metal plate and the protective film.

Accordingly, an end of the metal plate protrudes less than the protective film, thereby pressing less on the bending area of the display panel, and thus cracks occurring in the display panel may be prevented or reduced. In addition, when an engraved pattern is formed on the metal plate, the modulus of the metal plate may be reduced, thereby reducing the pressure applied to the display panel. Through this, the radius of curvature of the display panel may be reduced, thereby reducing a size of the peripheral area. In addition, since a protective film, etc. is not disposed between the metal plate and the display panel, a thickness of the display device itself may be reduced.

As a result, a reliable display device may be produced by reducing the pressure applied to the display panel through a length of the metal plate, pattern formation, etc., and convenience may be provided to a user through a reduction in the peripheral area and/or a reduction in the thickness of the display device.

### BRIEF DESCRIPTION OF THE DRAWINGS

The accompanying drawings, which are included to provide a further understanding of the inventive concept and are incorporated in and constitute a part of this specification, illustrate embodiments of the inventive concept together with the description.

FIG. 1 is a perspective view showing an embodiment of a display device according to the disclosure.

FIG. 2 is an exploded perspective view showing components of the display device of FIG. 1.

FIG. 3 is a plan view showing an embodiment of the display panel of FIG. 2.

FIG. 4 is a perspective view showing the display panel and the metal plate of FIG. 2.

FIG. 5 is a cross-sectional view showing an embodiment of the display device of FIG. 2 in a bent state.

FIG. 6 is a cross-sectional view showing an embodiment of the display panel of FIG. 5.

FIG. 7 is a cross-sectional view showing an embodiment of the display device of FIG. 5 in an unfolded state.

FIG. 8 is another cross-sectional view showing an embodiment of the display device of FIG. 5 in an unfolded state.

FIG. 9 is a cross-sectional view showing another embodiment of the display device of FIG. 2 in a bent state.

FIG. 10 is a cross-sectional view showing an embodiment of the display device of FIG. 9 in an unfolded state.

FIG. 11 is a cross-sectional view showing another embodiment of the display device of FIG. 9 in an unfolded state.

FIG. 12 is a plan view showing a cut embodiment of the metal plate of FIG. 10.

FIG. 13 is a perspective view showing another cut embodiment of the metal plate of FIG. 11.

FIG. 14 is a perspective view showing another cut embodiment of the metal plate of FIG. 11.

FIG. 15 is a block diagram showing an embodiment of an electronic device according to the disclosure.

FIG. 16 is a perspective view showing an embodiment in which the electronic device of FIG. 15 is implemented as a smartphone.

### DETAILED DESCRIPTION

Regarding embodiments of the disclosure disclosed in this text, specific structural and functional descriptions are merely illustrative for a purpose of explaining the embodiments of the disclosure, and the embodiments of the disclosure may be implemented in various forms and should not be construed as limited to the embodiments described in.

Since the disclosure may be subject to various changes and may have various forms, illustrative embodiments will be illustrated in the drawings and described in detail in the text. However, this is not intended to limit the disclosure to a specific disclosed form, and should be understood to include all changes, equivalents, and substitutes included in the spirit and technical scope of the disclosure.

Terms such as first, second, etc. may be used to describe various components, but the components should not be limited by the terms. The above terms may be used for a purpose of distinguishing one component from another component. For example, a first component may be referred to as a second component, and similarly, the second component may be referred to as a first component without departing from the scope of the disclosure.

It will be understood that when an element is referred to as being “connected” or “coupled” to another element, it may be directly connected or coupled to the other element or intervening element(s) may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for a purpose of describing particular embodiments only and is not intended to be limiting of the inventive concept. As used herein, the singular forms “a,” “an” and “the” are intended to include plural forms as well, unless the context clearly indicates otherwise. It will be further understood that the terms “comprises” and/or “comprising,” when used in this specification, specify a presence of stated features, integers, steps, operations, elements, and/or components, but do not preclude the presence or addition of one or more other features, integers, steps, operations, elements, components, and/or groups thereof.

Terms such as “below”, “at the bottom”, “lower”, “below”, “above”, “on top”, “on the top”, “on”, etc. is used to explain a relationship between components shown in the drawings. The terms are relative concepts and are explained based on the direction indicated in the drawings.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

Unless otherwise defined, all terms (including technical and scientific terms) used herein have a same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described in detail with reference to the accompanying drawings. Same reference numerals are used for same components in the drawings, and redundant descriptions of same components will be omitted.

In this specification, a plane may be defined by a first direction D1 and a second direction D2 that intersects the first direction D1. In an embodiment, the second direction D2 may be perpendicular to the first direction D1, for example. In addition, a third direction D3 may be a normal direction of the plane. That is, the third direction D3 may be perpendicular to the plane formed by the first direction D1 and the second direction D2.

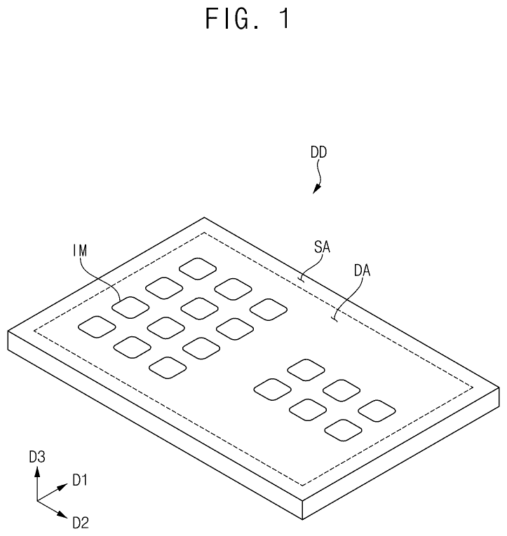

FIG. 1 is a perspective view showing an embodiment of a display device according to the disclosure.

Referring to FIG. 1, the display device DD may include a display area DA and a peripheral area SA. The display area DA may be at least partially surrounded by the peripheral area SA.

The display area DA may be an area that generates light or controls a transmittance of light provided from an external light source to display an image. The peripheral area SA may be an area where no images are displayed. However, embodiments of the disclosure are not necessarily limited thereto, and at least a portion of the peripheral area SA may also display an image.

The display area DA may display a plurality of images IM. Through these images IM, users may receive information from the display device DD.

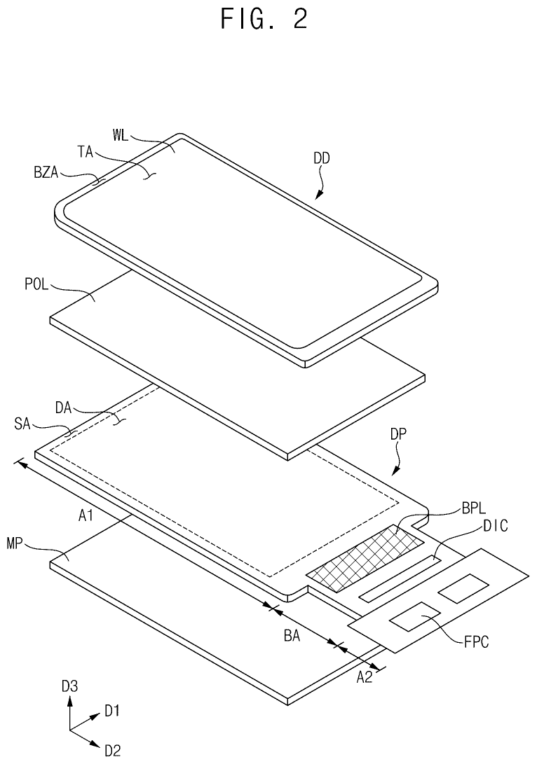

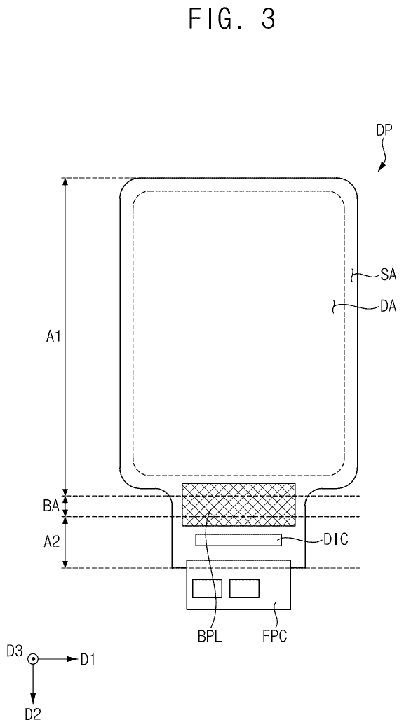

FIG. 2 is an exploded perspective view showing components of the display device of FIG. 1. FIG. 3 is a plan view showing an embodiment of the display panel of FIG. 2.

Referring to FIGS. 1, 2, and 3, the display device DD may include a metal plate MP, a display panel DP, a polymer layer POL, and a window layer WL.

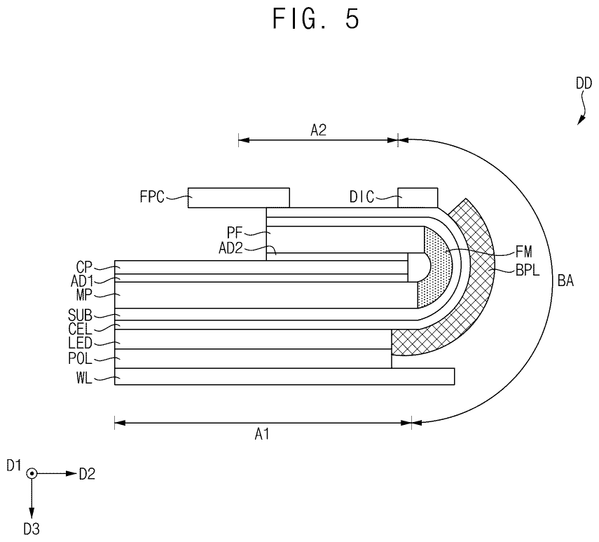

The metal plate MP may be disposed under the display panel DP. The metal plate MP may support the display panel DP and protect the display device DD from external impacts. length of one side of the metal plate MP and a pattern defined in the metal plate MP will be described later with reference to FIG. 5 and others.

The metal plate MP may include a metallic material. In an embodiment, the metal plate MP may include copper (Cu), aluminum (Al), stainless steel (“SUS”), etc., for example. These may be used alone or in any combinations with each other. However, embodiments of the disclosure are not necessarily limited thereto.

The display panel DP may be disposed on the metal plate MP. The display panel DP may include a first area A1 including the display area DA, a second area A2, and a bending area BA disposed between the first area A1 and the second area A2.

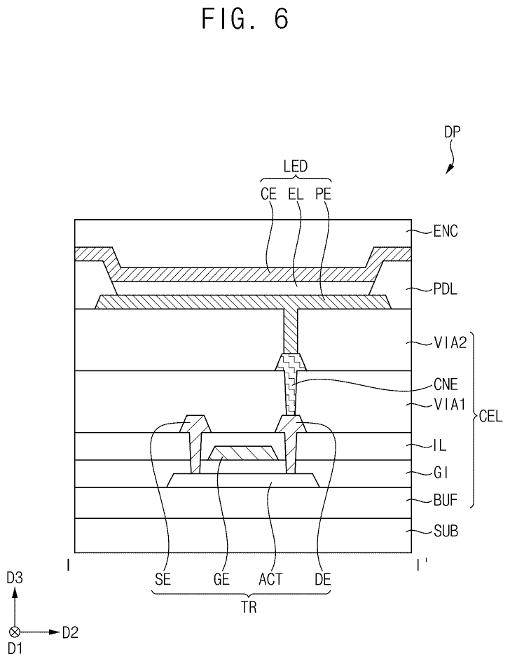

The first area A1 of the display device DD may include light-emitting diode (e.g., light-emitting diodes LED of FIG. 6). The cross-sectional view of the display panel DP including the light-emitting diode (e.g., the light-emitting element (e.g., light-emitting diode) LED of FIG. 6) will be described later with reference to FIG. 6.

A bending protection layer BPL may be disposed in the bending area BA of the display panel DP. Although the bending protection layer BPL is shown in FIG. 2 as being disposed only in the bending area BA, the bending protection layer BPL may also be disposed in portions of the first area A1 and/or the second area A2. The bending protection layer BPL may protect the bending area BA of the display panel DP from external impacts. In an embodiment, the bending protection layer BPL may include silicon-based resin, acrylic-based resin, or urethane-based resin, for example. These materials may be used alone or in combination, but embodiments of the disclosure are not necessarily limited thereto.

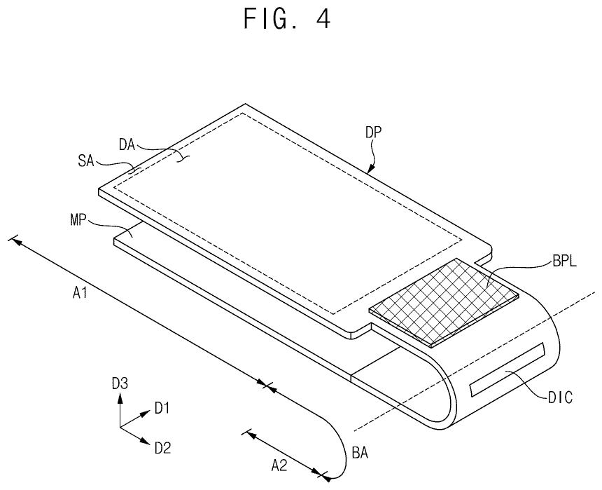

A driver chip DIC may be disposed in the second area A2 of the display panel DP. The display panel DP may provide visual information to users of the display device DD based on electrical signals transmitted from the driver chip DIC. The driver chip DIC may be disposed on a substrate (e.g., substrate SUB of FIG. 4) of the display device DD. That is, the driver chip DIC may be disposed (e.g., mounted) by a chip-on-plastic (“COP”) method.

A circuit board FPC may be attached to the second area A2 of the display panel DP. The circuit board FPC may be electrically connected to electronic components (e.g., a timing controller). A circuit board FPC may generate scan control signals, data control signals, and image data using the video signals and timing signals received from the electronic components. The scan control signals, the data control signals, and the image data may be provided to the driver chip DIC through the circuit board FPC.

The polymer layer POL may be disposed on the display panel DP. The polymer layer POL may adhere the display panel DP to the window layer WL. Additionally, the polymer layer POL may support the window layer WL to prevent sagging and protect the display panel DP from external impacts. The polymer layer POL may have a single-layer or multilayer structure.

The window layer WL may be disposed on the polymer layer POL. A front surface of the window layer WL may be divided into a transmission area TA and a bezel area BZA. The transmission area TA may be an area where the images IM are displayed and may correspond to the display area DA. That is, users may view the images IM through the transmission area TA. In this embodiment, the transmission area TA may have a rounded quadrangular shape, e.g., rounded rectangular shape, but embodiments of the disclosure are not necessarily limited thereto.

The bezel area BZA may surround the transmission area TA. Accordingly, a planar shape of the transmission area TA may be substantially defined by the bezel area BZA. The bezel area BZA may correspond to the peripheral area SA of the display device DD. The bezel area BZA may have a predetermined color, such as black or gray. However, embodiments of the disclosure are not necessarily limited thereto, and the bezel area BZA may be disposed next (adjacent) to only one side of the transmission area TA.

In FIG. 2, the display device DD includes the metal plate MP, the display panel DP, the polymer layer POL, and the window layer WL, but the disclosure is not necessarily limited thereto. Additional components such as a cover panel (e.g., cover panel CP of FIG. 5) may be included under the metal plate MP.

FIG. 4 is a perspective view showing the display panel and the metal plate of FIG. 2. Specifically, FIG. 4 shows the metal plate MP disposed under the display panel DP, and the bending area BA of the display panel DP is in a bent state.

Referring to FIGS. 2, 3, and 4, the bending area BA of the display panel DP may be bent around an imaginary line extending in the first direction D1. As the bending area BA of the display panel DP bends, the second area A2 may be disposed under the first area A1. In other words, the second area A2 of the display panel DP may be disposed to face the first area A1. As a result, components such as the circuit board FPC attached to the second area A2 may also be disposed under the first area A1.

As the display panel DP bends, a planar area of the display panel DP may be reduced compared to when it is not bent. Consequently, a size of the peripheral area SA of the display device DD may be reduced, and convenience of use may be provided to a user of the display device DD.

FIG. 5 is a cross-sectional view showing an embodiment of the display device of FIG. 2 in a bent state.

Referring to FIGS. 2 and 5, the display device DD may include the cover panel CP, a first adhesive layer AD1, the metal plate MP, a substrate SUB, a circuit element layer CEL, a light-emitting element LED, the polymer layer POL, the window layer WL, the bending protection layer BPL, a filler material FM, a second adhesive layer AD2, a protective film PF, the driver chip DIC, and a circuit board FPC. The metal plate MP, the polymer layer POL, the window layer WL, the bending protection layer BPL, the driver chip DIC, and the circuit board FPC have been described with reference to FIG. 2, and therefore, overlapping content may be omitted or simplified.

The cover panel CP may be disposed under the metal plate MP. The cover panel CP may be disposed in the first area A1 of the display panel DP. The cover panel CP may protect the display panel DP from external impacts or foreign material intrusion. The cover panel CP may have a multilayer structure, including a support layer, a heat dissipation layer, and a cushioning layer for absorbing shocks.

In an embodiment, the cover panel CP may include conductive materials. As the cover panel CP includes conductive materials, the cover panel CP may perform a discharge function of the display device DD. That is, static electricity generated in the circuit board FPC or other components may be discharged through the cover panel CP, the display device DD may be protected.

The first adhesive layer AD1 may be disposed on the cover panel CP. The first adhesive layer AD1 may adhere the cover panel CP to the metal plate MP. The first adhesive layer AD1 may include materials such as optically clear adhesive (“OCA”), optically clear resin (“OCR”), or pressure-sensitive adhesive (“PSA”). These may be used alone or in any combinations with each other. However, the embodiment of this disclosure is not necessarily limited thereto.

The metal plate MP may be disposed on the first adhesive layer AD1. The metal plate MP may protect the light-emitting element LED from external impacts.

In an embodiment, at least a portion of the metal plate MP may protrude from the first area A1 to the bending area BA in the second direction D2. Specifically, the metal plate MP may cover not only the first area A1 but also portion of the bending area BA in a plan view to protect the light-emitting element LED.

The substrate SUB may be disposed on the metal plate MP. The substrate SUB may include materials such as glass, metal, or plastic. In an embodiment, a plastic substrate may include polyimide, for example. Accordingly, the substrate, as shown in FIG. 5, may be flexible substrate. However, the embodiment of disclosure is not necessarily limited thereto, and the substrate SUB may include inorganic, organic, or composite layers.

In an embodiment, the substrate SUB may be bent along an imaginary line extending in the first direction D1. Accordingly, the substrate SUB may have a curvature radius in a cross-sectional view. The curvature radius may be about 0.5 millimeter (mm) or less. Preferably, the curvature radius about 0.4 mm or less. As the radius of curvature of the substrate SUB satisfies the above-described range, a thickness of the display device DD in the third direction D3 may be minimized.

In an embodiment, one surface of the substrate SUB may be in direct contact with one surface of the metal plate MP. As shown in FIG. 5, the substrate SUB may be disposed in contact with the metal plate MP. That is, a configuration such as the protective film PF may not be placed between the substrate SUB and the metal plate MP in a cross-sectional view.

Since the substrate SUB and the metal plate MP are in direct contact without additional configuration, a thickness of the display device DD in the third direction D3 may be relatively thinned. Accordingly, a manufacturing process for the display device DD may be simplified, and a manufacturing cost of the display device DD may be reduced. In addition, since a thickness of the display device DD is thinned, convenience may be provided to a user of the display device DD. In addition, since a radius of curvature of the display panel DP is reduced, a thickness of the display device DD may be thinned.

The circuit element layer CEL may be disposed on the substrate SUB. The circuit element layer CEL may be disposed to correspond to an upper surface of the substrate SUB. In an embodiment, the circuit element layer CEL may have a flat plane at a location corresponding to the first area A1 and the second area A2, and may have a surface that is bent at a location corresponding to the bending area BA, for example. The circuit element layer CEL may include metals (e.g., the switching element (e.g., transistor) TR of FIG. 6) that transmit a signal from the driver chip DIC to the light-emitting element LED. The configuration of the circuit element layer CEL, etc. will be described later with reference to FIG. 6.

The light-emitting element LED may be disposed on the circuit element layer CEL. The light-emitting element LED may emit light to provide information to users. Details regarding the light-emitting element LED are described with reference to FIG. 6.

The bending protection layer BPL may be disposed on the bending area BA of the substrate SUB. The bending protection layer BPL may contact the substrate SUB or the circuit element layer CEL. The bending protection layer BPL may protect the bending area BA of the substrate SUB from external impacts and prevent cracks as the bending protection layer BPL is disposed outer side of the substrate SUB. In addition, the bending protection layer BPL may also prevent cracks, etc. from occurring in the substrate SUB in the bending area BA when the substrate SUB is bent.

The bending protection layer BPL may include silicon-based resin, acrylic-based resin, or urethane-based resin. These may be used alone or in any combinations with each other. However, the embodiment of this disclosure is not necessarily limited thereto.

The polymer layer POL may be disposed on the light-emitting element LED. The polymer layer POL may prevent sagging of the window layer WL or protect the light-emitting element LED from external impacts.

The window layer WL may be disposed on the polymer layer POL. The window layer WL may be disposed in the first area A1 and/or the second area A2. The window layer WL may include glass or synthetic resin films. These may be used alone or in any combinations with each other. However, the embodiment of this disclosure is not necessarily limited thereto.

In FIG. 5, the window layer WL is illustrated as having a flat shape, but the embodiment of the disclosure is not necessarily limited thereto. The window layer WL may have a shape that is bent in the second direction D2 in the cross-sectional view. In addition, a functional layer such as an anti-reflection layer, an anti-reflection layer, and/or an anti-fingerprint layer may be further disposed on the window layer WL.

A protective film PF may be disposed under the cover panel CP. A portion of the protective film PF may protrude from the second area A2 to the bending area BA. Specifically, the protective film PF may protrude in the second direction D2 from the second area A2.

In an embodiment, an edge of the protective film PF may protrude further in the second direction D2 than an edge of the metal plate MP. That is, a degree to which the protective film PF protrudes from the second area A2 to the bending area BA may be greater than a degree to which the metal plate MP protrudes from the first area A1 to the bending area BA. By having an edge of the metal plate MP protrude less than an edge of the protective film PF, a pressure exerted by the metal plate MP on the display panel DP may be reduced. As a result, a pressure that the metal plate MP applies to the display panel DP is reduced, so that a phenomenon in which cracks or the like occur in the display panel DP may be prevented or reduced.

FIG. 6 is a cross-sectional view showing an embodiment of the display panel of FIG. 5.

Referring to FIGS. 1, 5, and 6, the display panel DP may include a substrate SUB, the circuit element layer CEL, the light-emitting element LED, and an encapsulation layer ENC. The circuit element layer CEL may include a buffer layer BUF, a gate insulating layer GI, the switching element TR, an inter-insulating layer IL, a connection electrode CNE, a first via layer VIA1, a second via layer VIA2, a light-emitting element LED, and a pixel defining layer PDL.

The switching element TR may include an active layer ACT, a gate electrode GE, a source electrode SE, and a drain electrode DE. The light-emitting element LED may include a pixel electrode PE, an emission layer EL, and a common electrode CE.

The substrate SUB may include a glass substrate, a metal substrate, a plastic substrate, etc. In an embodiment, the plastic substrate of the substrate SUB may include polyimide, for example. However, the disclosure is not limited thereto, and the substrate SUB may be an inorganic layer, an organic layer, or a composite material layer.

The buffer layer BUF may be disposed on the substrate SUB. The buffer layer BUF may prevent impurities such as oxygen and moisture from penetrating into an upper portion of the substrate SUB through the substrate SUB. The buffer layer BUF may include an inorganic insulating material.

The active layer ACT may be disposed on the buffer layer BUF. The active layer ACT may include an oxide semiconductor, a silicon semiconductor, an organic semiconductor, etc. In an embodiment, the oxide semiconductor may include at least one oxide selected from indium (In), gallium (Ga), tin (Sn), zirconium (Zr), vanadium (V), hafnium (Hf), cadmium (Cd), germanium (Ge), chromium (Cr), titanium (Ti), and zinc (Zn), for example. The silicon semiconductor may include amorphous silicon, polycrystalline silicon, etc. The active layer ACT may include a source region, a drain region, and a channel region disposed between the source region and the drain region.

The gate insulating layer GI may be disposed on the buffer layer BUF. Specifically, the gate insulating layer GI may cover the active layer ACT on the buffer layer BUF. The gate insulating layer GI may include an inorganic insulating material. In an embodiment, the gate insulating layer GI may be disposed entirely over the display area DA and the peripheral area SA. In an embodiment, the gate insulating layer GI may be disposed only under the gate electrode GE.

The gate electrode GE may be disposed on the gate insulating layer GI. The gate electrode GE may at least partially overlap the channel region of the active layer ACT. The gate electrode GE may include a conductive material such as a metal, alloy, conductive metal nitride, conductive metal oxide, or transparent conductive material. In embodiments, the conductive material that may be used in the gate electrode GE may include gold (Au), silver (Ag), aluminum (Al), platinum (PT), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), alloy including or consisting of aluminum, alloy including or consisting of silver, alloy including or consisting of copper, alloy including or consisting of molybdenum, aluminum nitride (AlN), tungsten nitride (WN), titanium nitride (TiN), chromium nitride (CrN), tantalum nitride (TaN), strontium ruthenium oxide (SrRuO), zinc oxide (ZnO), indium tin oxide (“ITO”), tin oxide (SnO), indium oxide (InO), gallium oxide (GaO), indium zinc oxide (“IZO”), etc. These may be used alone or in any combinations with each other. In an alternative embodiment, the gate electrode GE may have a single-layer structure or a multi-layer structure including a plurality of conductive layers.

The inter-insulating layer IL may be disposed on the gate electrode GE. Specifically, the inter-insulating layer IL may be disposed on the gate insulating layer GI and cover the gate electrode GE on the gate insulating layer GI. The inter-insulating layer IL may include an inorganic insulating material.

The source electrode SE and the drain electrode DE may be disposed on the inter-insulating layer IL. Each of the source electrode SE and the drain electrode DE may be connected to the active layer ACT. In an embodiment, the source electrode SE may contact the source region of the active layer ACT, and the drain electrode DE may contact the drain region of the active layer ACT, for example. Each of the source electrode SE and the drain electrode DE may include a conductive material. The active layer ACT, the gate electrode GE, the source electrode SE, and the drain electrode DE may form the switching element TR.

The first via layer VIA1 may be disposed on the source electrode SE and the drain electrode DE. Specifically, the first via layer VIA1 may be disposed on the inter-insulating layer IL and cover the source electrode SE and the drain electrode DE on the inter-insulating layer IL. The first via layer VIA1 may include an organic insulating material. In an embodiment, the first via layer VIA1 may be formed only in the display area DA and a portion of the peripheral area SA next (adjacent) to the display area DA.

The connection electrode CNE may be disposed on the first via layer VIA1. The connection electrode CNE may transmit a signal transmitted from the switching element TR to the light-emitting element LED. The connection electrode CNE may include metal, alloy, metal nitride, conductive metal oxide, transparent conductive material, etc. These may be used alone or in any combinations with each other. However, embodiments of the disclosure are not necessarily limited thereto.

The second via layer VIA2 may be disposed on the connection electrode CNE. Specifically, the second via layer VIA2 may be disposed on the first via layer VIA1 and cover the connection electrode CNE. The second via layer VIA2 may include substantially a same material as that of the first via layer VIA1.

The pixel electrode PE may be disposed on the second via layer VIA2. The pixel electrode PE may include a conductive material. The pixel electrode PE may be connected to the drain electrode DE through the connection electrode CNE. Accordingly, the pixel electrode PE may be electrically connected to the switching element TR.

The pixel defining layer PDL may be disposed on the pixel electrode PE. In an embodiment, the pixel defining layer PDL may expose at least a portion of the pixel electrode PE, for example. The pixel defining layer PDL may include an inorganic insulating material or an organic insulating material.

The emission layer (hereinafter also referred to as a light-emitting layer) EL may be disposed on the pixel electrode PE. Specifically, the light-emitting layer EL may be disposed within an opening defined by the pixel defining layer PDL. That is, the light-emitting layer EL may be surrounded by the pixel defining layer PDL. The light-emitting layer EL may include at least one of organic light-emitting material and/or quantum dots. However, embodiments of the disclosure are not necessarily limited thereto.

The common electrode CE may be disposed on the light-emitting layer EL. The common electrode CE may also be disposed on the pixel defining layer PDL. That is, the common electrode CE may be continuously disposed on the light-emitting layer EL and the pixel defining layer PDL. The common electrode CE may include a conductive material. The light-emitting layer EL may emit light based on voltage difference between the pixel electrode PE and the common electrode CE.

The encapsulation layer ENC may be disposed on the common electrode CE. The encapsulation layer ENC may include at least one inorganic encapsulation layer and at least one organic encapsulation layer. In an embodiment, the inorganic encapsulation layer and the organic encapsulation layer may be alternately disposed. In an embodiment, the organic encapsulation layer may include a cured polymer such as polyacrylate, epoxy resin, or silicone resin, for example. In an embodiment, the inorganic encapsulation layer may include silicon oxide, silicon nitride, silicon carbide, aluminum oxide, tantalum oxide, hafnium oxide, zirconium oxide, titanium oxide, etc., for example.

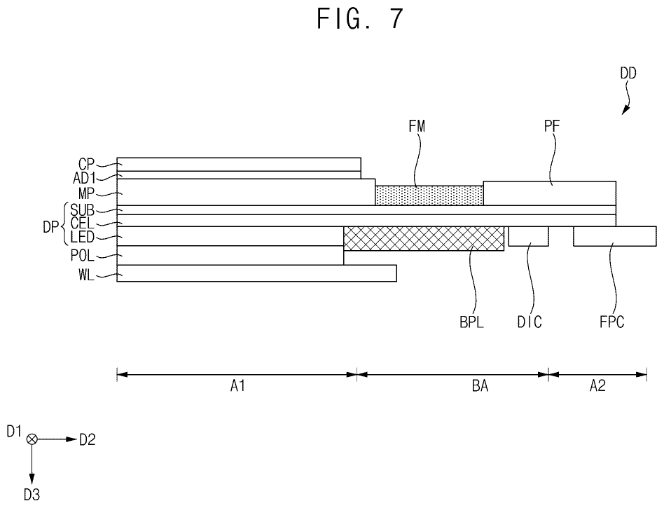

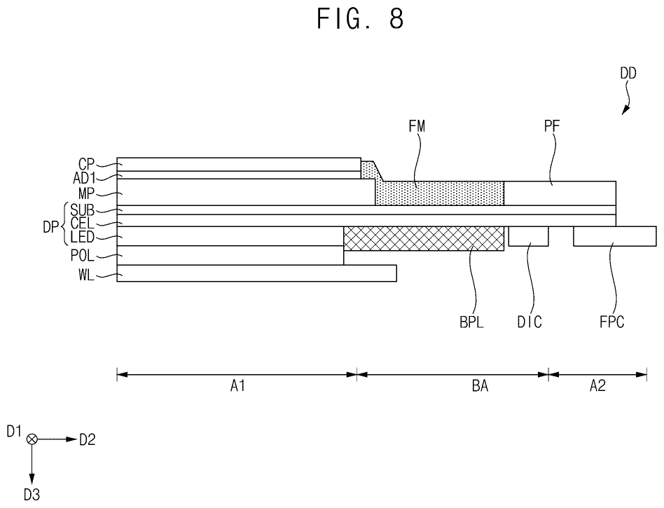

FIG. 7 is a cross-sectional view showing an embodiment of the display device of FIG. 5 in an unfolded state. FIG. 8 is another cross-sectional view showing an embodiment of the display device of FIG. 5 in an unfolded state. Specifically, since FIGS. 7 and 8 show the unfolded state of the display device DD of FIG. 5, overlapping descriptions may be omitted or simplified. FIGS. 7 and 8 describe shape and arrangement of the filler material FM.

Referring to FIGS. 5, 7, and 8, the filler material FM may be disposed between the metal plate MP and the protective film PF. When the display device DD is unfolded, the metal plate MP and the protective film PF may be spaced apart in the second direction D2 with the filler material FM in between. The filler material FM may be disposed under the bending area BA of the substrate SUB to prevent cracks or damage when the substrate SUB bends.

In an embodiment, the filler material FM may include at least one of a silicon-based resin, an acrylic-based resin, or a urethane-based resin. These may be used alone or in any combinations with each other. That is, the filler material FM may include substantially a same material as that of the bending protection layer BPL. However, the embodiments of the disclosure are not necessarily limited thereto.

In an embodiment, as shown in FIG. 7, the filler material FM may contact portions of side surfaces of both the metal plate MP and the protective film PF. That is, a height of an upper surface of the filler material FM may be lower than heights of an upper surfaces of each of the metal plate MP and the protective film PF.

In an embodiment, the filler material FM may cover at least a portion of an upper surface of the metal plate MP, as shown in FIG. 8. As the filler material FM covers at least a portion of an upper surface of the metal plate MP, an adhesive strength between the filler material FM and the metal plate MP may be improved. In addition, the filler material FM may contact at least a portion of one side of the cover panel CP disposed on the metal plate MP. That is, the filler material FM may be disposed between the metal plate MP and the protective film PF, and may contact the metal plate MP and/or the cover panel CP, thereby improving the adhesive strength within the display device DD. Accordingly, a reliability of the durability of the display device DD may be improved.

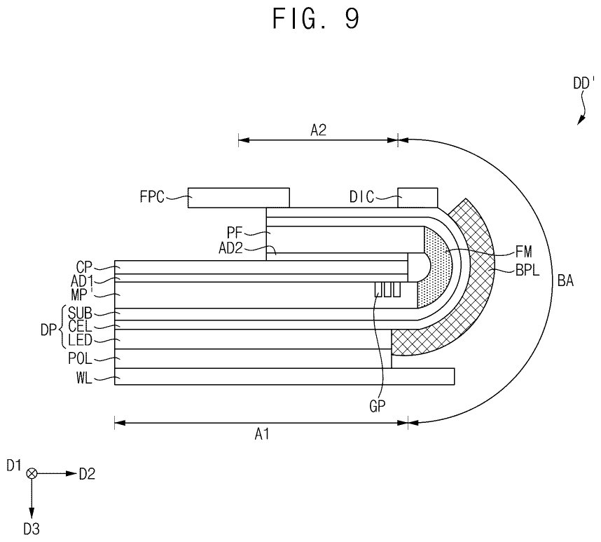

FIG. 9 is a cross-sectional view showing another embodiment of the display device of FIG. 2 in a bent state. Specifically, the display device DD′ shown in FIG. 9 is substantially same as the display device DD shown in FIG. 5, except for the cross-sectional shape of the metal plate MP′. Therefore, overlapping details may be omitted or simplified.

Referring to FIGS. 2, 5, and 9, the display device DD′ may include the cover panel CP, the first adhesive layer AD1, the metal plate MP′, the substrate SUB, the circuit element layer CEL, the light-emitting element LED, the polymer layer POL, the window layer WL, the bending protection layer BPL, the filler material FM, the second adhesive layer AD2, the protective film PF, the driver chip DIC, and the circuit board FPC.

The metal plate MP′ may be disposed on the first adhesive layer AD1. The metal plate MP′ may protect the light-emitting element LED from external impacts. As shown in FIG. 9, an engraved pattern GP may be defined on one surface of the metal plate MP′ in a thickness direction (e.g., the third direction D3) of the metal plate MP′.

In an embodiment, the metal plate MP′ may include an engraved pattern GP in a portion next (adjacent) to the bending area BA. Specifically, the engraved pattern GP may be defined by removing material from an upper surface of the metal plate MP′ in the third direction D3. By defining the engraved pattern GP, a modulus of the metal plate MP′ may be relaxed. Accordingly, when the display device DD′ is bent, the metal plate MP′ may be bent. As a result, a phenomenon of crack may be prevented or reduced as the metal plate MP′ bends with the substrate SUB.

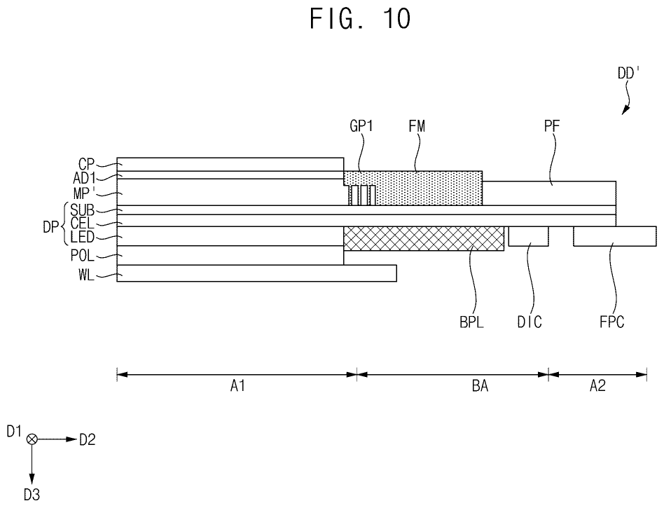

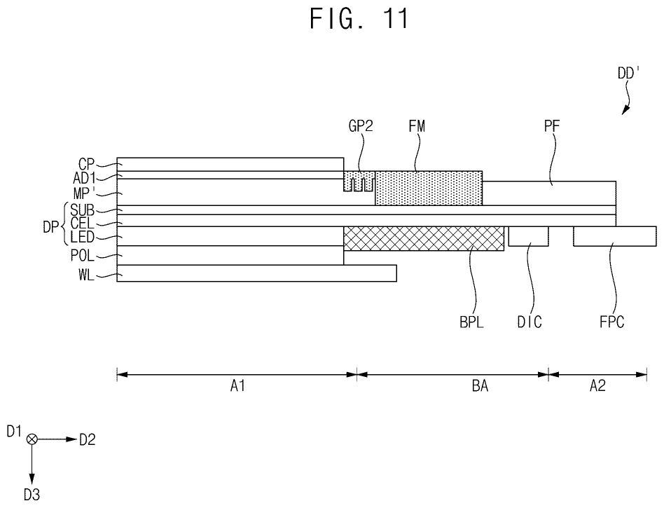

FIG. 10 is a cross-sectional view showing an embodiment of the display device of FIG. 9 in an unfolded state. FIG. 11 is a cross-sectional view showing another embodiment of the display device of FIG. 9 in an unfolded state. Specifically, the display device DD′ shown in FIGS. 10 and 11 is substantially same as the display device DD shown in FIGS. 7 and 8, except for the metal plate MP. Therefore, overlapping details may be omitted or simplified.

Referring to FIGS. 9, 10, and 11, the metal plate MP′ may include the engraved pattern GP in a portion next (adjacent) to the bending area BA. In an embodiment, the engraved pattern GP may be a first engraved pattern GP1 illustrated in FIG. 10 or a second engraved pattern GP2 illustrated in FIG. 11, for example.

In an embodiment, as shown in FIG. 10, the first engraved pattern GP1 may be defined in the portion of the metal plate MP′ next (adjacent) to the bending area BA. The first engraved pattern GP1 may have a hole shape that penetrates through the metal plate MP′ in a thickness direction of the metal plate MP′ in a cross-sectional view. That is, the first engraved pattern GP1 may be multiple holes defined in the metal plate MP′ penetrating in the third direction D3. As the first engraved pattern GP1 is defined in the metal plate MP′, at least a portion of an upper surface of the substrate SUB may be exposed.

The filler material FM may fill the first engraved pattern GP1 defined in the metal plate MP′. Specifically, the filler material FM may be disposed between the metal plate MP′ and the protective film PF and fill the first engraved pattern GP1 of the metal plate MP′. By filling the first engraved pattern GP1, an adhesive strength between the metal plate MP′ and the filler material FM may be enhanced.

In an embodiment, as shown in FIG. 11, the second engraved pattern GP2 may be defined in a portion of the metal plate MP′ next (adjacent) to the bending area BA. The second engraved pattern GP2 may have a groove shape in a cross-sectional view, where material is removed from the metal plate MP′ without penetrating through the metal plate MP′.

As with reference to FIG. 10, in FIG. 11, the filler material FM may fill the second engraved pattern GP2 defined in the metal plate MP′. Specifically, the filler material FM is disposed between the metal plate MP′ and the protective film PF, and may fill the second engraved pattern GP2 of the metal plate MP′. As the filler material FM fills the second engraved pattern GP2 of the metal plate MP′, an adhesive strength of the metal plate MP′ and the filler material FM may be enhanced.

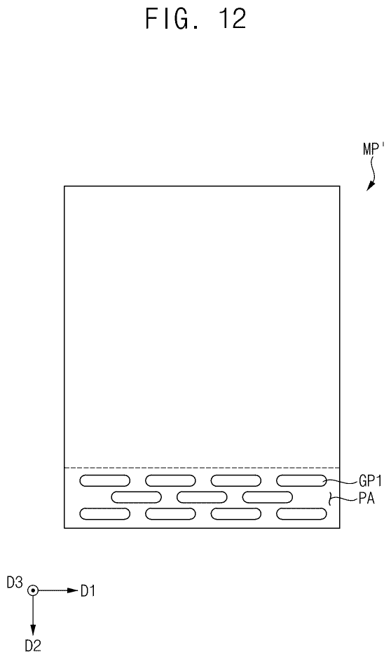

FIG. 12 is a plan view showing an embodiment of the cut metal plate MP′ of FIG. 10.

Referring to FIGS. 10 and 12, a pattern region PA may be defined on one side of the metal plate MP'. Specifically, the pattern region PA may be defined on a portion of the metal plate MP′ next (adjacent) to the bending area BA. In the pattern region PA, multiple first engraved patterns GP1 may be defined. In an embodiment, the first engraved pattern GP1 may penetrate through the metal plate MP′ in the third direction D3, for example. That is, the first engraved patterns GP1 may penetrate from an upper surface of the metal plate MP′ to an upper surface of the substrate SUB.

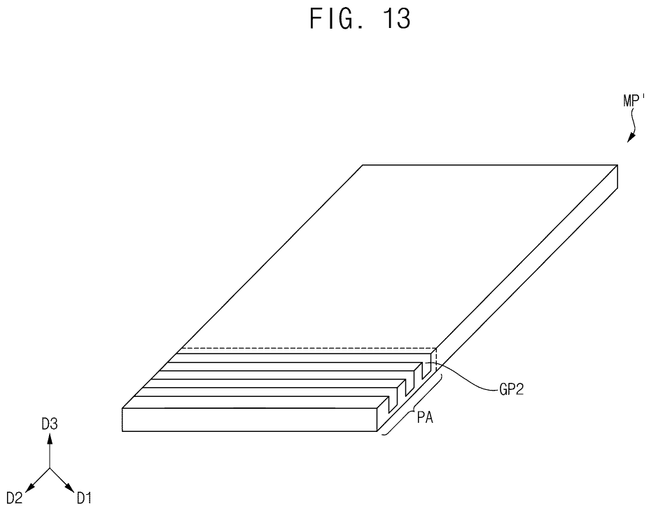

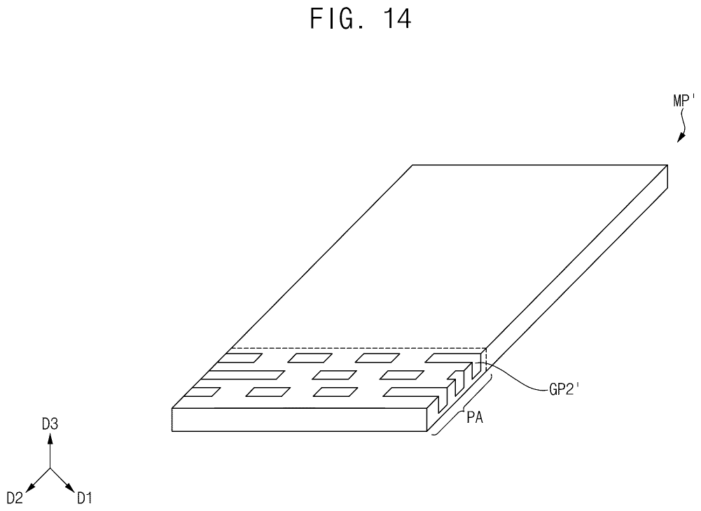

FIG. 13 is a perspective view showing another cut embodiment of the metal plate of FIG. 11. FIG. 14 is a perspective view showing another cut embodiment of the metal plate of FIG. 11.

Referring to FIGS. 11 and 13, the pattern region PA of the metal plate MP′ may include second engraved patterns GP2. As shown in FIG. 13, the second engraved patterns GP2 may extend in the width direction of the metal plate MP′. The second engraved patterns GP2 may have a groove shape created by removing material in the thickness direction of the metal plate MP′ in a cross-sectional view, and may have a shape extend in the first direction D1 in a plan view. However, the embodiments of the disclosure are not necessarily limited thereto.

Referring further to FIGS. 11 and 14, the second engraved patterns GP2′ may, as shown in FIG. 14, have groove shapes spaced apart from each other in the pattern region PA in the first direction D1 and/or the second direction D2.

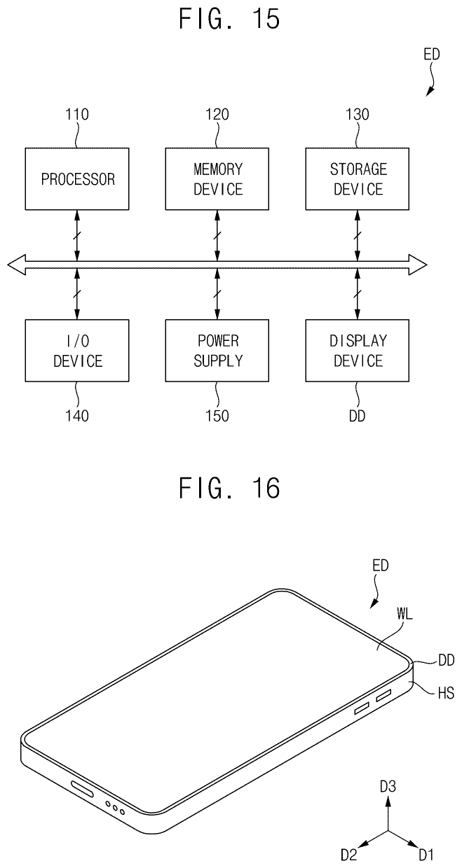

FIG. 15 is a block diagram showing an embodiment of an electronic device according to the disclosure. FIG. 16 is a perspective view showing an embodiment in which the electronic device of FIG. 15 is implemented as a smartphone.

Referring to FIGS. 15 and 16, an electronic device ED may include a processor 110, a memory device 120, a storage device 130, an input/output (“IO”) device 140, a power supply 150, and the display device DD. The display device DD included in the electronic device ED may be the display device DD of FIG. 1. Additionally, the electronic device ED may further include various ports to communicate with video cards, sound cards, memory cards, universal serial bus (“USB”) devices, or other systems.

The processor 110 may perform predetermined calculations or tasks. In an embodiment, the processor 110 may be a microprocessor, a central processing unit (“CPU”), or an application processor. The processor 110 may be connected to other components through buses such as an address bus, a control bus, and a data bus. In an embodiment, the processor 110 may also be connected to an expansion bus, such as a Peripheral Component Interconnect (“PCI”) bus. The processor 110 may output data control signals and image data to the timing controller.

The memory device 120 may store data desired for an operation of the electronic device ED. In an embodiment, the memory device 120 may include non-volatile memory devices such as erasable programmable read-only memory (“EPROM”), electrically erasable programmable read-only memory (“EEPROM”), flash memory, phase-change random access memory (“PRAM”), resistance random access memory (“RRAM”), nano floating gate memory (“NFGM”), polymer random access memory (“PoRAM”), magnetic random access memory (“MRAM”), ferroelectric random access memory (“FRAM”), and/or volatile memory devices such as dynamic random access memory (“DRAM”), static random access memory (“SRAM”), or mobile DRAM, for example.

The storage device 130 may include solid-state drives (“SSD”), hard disk drives (“HDD”), or compact disc read-only memory (“CD-ROMs”). The IO device 140 may include input means such as a keyboard, keypad, touchpad, touchscreen, or mouse and output means such as speakers or printers. In an embodiment, the display device DD may be included as part of the IO device 140. The power supply 150 may supply power desired for an operation of the electronic device ED. The display device DD may be connected to other components through buses or communication links.

In an embodiment, as shown in FIG. 16, the electronic device ED may be implemented as a smartphone. The electronic device ED may include the window layer WL, the display device DD, and a housing HS.

The window layer WL may cover the display device DD. In an embodiment, the window layer WL may be disposed on the display area DA of the display device DD (e.g., the display area DA of FIG. 1) to protect the display area DA where images are displayed, for example.

The housing HS may surround the display device DD. In an embodiment, the display device DD may be accommodated within the housing HS, which may cover its sides and bottom, for example. The housing HS may provide additional rigidity and protect the display device DD from external impacts.

Functional modules such as a camera module or a sensor module may be housed within the housing HS. These functional modules may be electrically connected to the display device DD to perform predetermined functions. However, type and arrangement of the functional modules are not necessarily limited thereto.

What is claimed is:

1. A display device comprising:
a display panel including:
a first area including a display area;
a second area; and
a bending area disposed between the first area and the second area in an unfolded state;
a metal plate disposed under the display panel in the first area, directly contacting the display panel, and at least partially protruding from the first area to the bending area in a plan view;
a protective film disposed under the display panel in the second area and protruding from the second area to the bending area further than the metal plate protrudes from the first area to the bending area when the display panel is in a bent state in the plan view; and
a filler material disposed under the display panel in the bending area and filling a space between the metal plate and the protective film.

2. The display device of claim 1, wherein a curvature radius of the bending area of the display panel is about 0.5 millimeter or less.

3. The display device of claim 1, further comprising
a cover panel disposed between the metal plate and the protective film when the display panel is in the bent state and protecting the display panel.

4. The display device of claim 3, wherein the filler material contacts at least a portion of one side of the cover panel.

5. The display device of claim 1, wherein the filler material includes at least one selected from a group including a silicon-based resin, an acrylic-based resin, and a urethane-based resin.

6. The display device of claim 1, further comprising a bending protection layer disposed on the display panel in the bending area.

7. The display device of claim 6, wherein the filler material and the bending protection layer include a same material as each other.

8. The display device of claim 1, wherein the display panel includes a substrate including polyimide.

9. A display device comprising:
a display panel including:
a first area including a display area;
a second area; and
a bending area disposed between the first area and the second area in an unfolded state;
a metal plate disposed under the display panel in the first area and directly contacting the display panel, the metal plate including:
an engraved pattern defined in a thickness direction of the metal plate at a portion next to the bending area;
a protective film disposed under the display panel in the second area; and
a filler material disposed under the display panel in the bending area and filling a space between the metal plate and the protective film.

10. The display device of claim 9, wherein the engraved pattern includes multiple holes defined in the metal plate and penetrating in the thickness direction of the metal plate.

11. The display device of claim 9, wherein the engraved pattern includes grooves partially removed from the thickness direction of the metal plate in the plan view.

12. The display device of claim 9, wherein the filler material covers at least a portion of an upper surface of the engraved pattern.

13. The display device of claim 9, wherein a curvature radius of the bending area of the display panel is about 0.5 millimeter or less.

14. The display device of claim 9, further comprising
a cover panel disposed between the metal plate and the protective film when the display panel is in the bent state and protecting the display panel.

15. The display device of claim 14, wherein the filler material contacts at least a portion of one side of the cover panel.

16. The display device of claim 9, wherein the filler material includes at least one selected from a group including a silicon-based resin, an acrylic-based resin, and a urethane-based resin.

17. The display device of claim 9, further comprising a bending protection layer disposed on the display panel in the bending area.

18. The display device of claim 17, wherein the filler material and the bending protection layer include a same material as each other.

19. The display device of claim 9, wherein the display panel includes a substrate comprising polyimide.

20. An electronic device comprising:
a housing; and
a display device accommodated by the housing and configured to display images, the display device including:
a display panel including:
a first area including a display area;
a second area; and
a bending area disposed between the first area and the second area in an unfolded state;
a metal plate disposed under the display panel in the first area, directly contacting the display panel, and at least partially protruding from the first area to the bending area in a plan view;
a protective film disposed under the display panel in the second area and protruding from the second area to the bending area further than the metal plate protrudes from the first area to the bending area when the display panel is in a bent state in the plan view; and
a filler material disposed under the display panel in the bending area and filling a space between the metal plate and the protective film.
